(19) United States
(12) Patent Application Publication
(10) Pub. No.: US 2025/0318091 A1
(43) Pub. Date: Oct. 9, 2025

(54) Temperature Controlled Power Storage and Delivery Systems

(71) Applicant: Power Up Connect LLC, Baltimore, MD (US)

(72) Inventors: Jay STEINMETZ, Baltimore, MD (US); Scott A. CALHOUN, Baltimore, MD (US); Mwamburi MKAYA, Baltimore, MD (US)

(73) Assignee: Power Up Connect LLC, Baltimore, MD (US)

(21) Appl. No.: 18/630,296

(22) Filed: Apr. 9, 2024

(51) Int. Cl. H05K 7/20; F25B 21/02; H02J 7/35; H02S 20/30

(52) U.S. Cl. CPC H05K 7/20918; F25B 21/02; H02J 7/35; H02S 20/30; H05K 7/20936; H05K 7/20945; F25B 2321/0252; H02J 2207/20

(57) ABSTRACT

Disclosed are methods, systems, apparatus, devices, and other implementations, including a power system that includes at least one battery to supply direct current (DC) power, and at least one power inverter electrically coupled to a respective one of the at least one battery, with the at least one power inverter module configured to convert DC outputted by the at least one battery into alternating current (AC) supplied to one or more loads. The power system further includes at least one dedicated cooling unit physically coupled to at least a part of the respective one of the at least one power inverter module to control the temperature of the at least one power inverter.

### TECHNICAL FIELD

The present disclosure relates generally to systems for power storage and delivery, and more particularly power storage and delivery systems with dedicated temperature control for components thereof.

### BACKGROUND

With ongoing electrification of civic infrastructure from machines and appliances that rely on fossil fuels, to machine and appliances that rely on renewable energy (such as solar energy, wind energy), large scale storage of renewable energy has become central to realizing this electrification. Many applications and systems still require AC power for operation, but may not have easy access to the electrical grid (e.g., in situations involving outdoor events in isolated areas). The traditional solution for such situations is to use an electric generators. However, this solution is at odds with the movement to the use of clean energy. Furthermore, AC generators (particularly small and medium size generators) require an uninterrupted supply of fuel, which presents its own logistical problems. On the other hand, solutions that rely on clean energy, such as using DC power storage devices (i.e., batteries), and one or more inverters to convert DC power to AC power suffer from power conversion inefficiencies as a result of changes to operating conditions, and in particular the operating temperature.

### SUMMARY

In one aspect, a power system is provided that includes at least one battery to supply direct current (DC) power, and at least one power inverter electrically coupled to a respective one of the at least one battery, with the at least one power inverter module configured to convert DC outputted by the at least one battery into alternating current (AC) supplied to one or more loads, and at least one dedicated cooling unit physically coupled to at least a part of the respective one of the at least one power inverter module to control the temperature of the at least one power inverter.

Embodiments of the system may include at least some of the features described in the present disclosure, including one or more of the following features.

The at least one power inverter can include a power inversion circuit to produce output AC from input DC supplied by the at least one battery, an inverter housing in which the power inversion circuit is disposed, and a heat draining contact disposed on the inverter housing and being in thermal communication with the power inversion circuit so as to receive thermal energy produced by the power inversion circuit during operation. The at least one cooling unit can be attached to the heat draining contact to thermally control temperature of the at least one power inverter.

The heat draining contact may include one or more heat conductive elements inserted into complementary depressions in walls defining the inverter housing, with the one or more heat conductive elements connected to one or more heat guides delivering heat produced by the power inversion circuitry to the one or more heat conductive elements.

The one or more heat guides can include one or more of, for example, heat conductive wiring, and/or tubing containing two-phase coolants.

The at least one cooling unit may include a solid-state heat pump with a contact element physically attached to a heated portion of the at least one power inverter, with the solid-state heat pump causing, when in operation, transfer of heat from the contact element to another portion of the solid-state heat pump located remotely from the heated portion of the at least one power inverter.

The solid state heat pump may include a proximal substrate attached to the heated portion of the at least one power inverter, a distal substrate opposite the proximal substrate, one or more thermoelectric coolers (TEC) disposed between the proximal substrate and the distal substrate, and a controller to control current flowing through the one or TEC based on measured temperature of the at least one power inverter.

The controller configured to control the current may be configured to increase the current flowing through the one or more TEC, in response to an increase of the measured temperature of the at least one power inverter, to transfer heat from the proximal substrate to the distal substrate.

The system may further include an exhaust fan module to remove heat captured by the solid-state heat pump.

The at least one cooling unit can include one or more of, for example, a DC-operated air conditioning unit, a magnetocaloric-based cooling mechanism, and/or a an electrocaloric cooling mechanism.

The system may further include at least one solar panel to capture solar energy, and convert the solar energy to electrical energy stored in the at least one battery.

The system may further include a vehicle trailer comprising multiple batteries that include the at least one battery, the vehicle trailer including a housing with a roof, wherein the at least one solar panel is mounted proximate the roof of the vehicle trailer.

The at least one solar panel can be pivotally displaceable between a covered position in which the at least one solar panel encloses an opening of the housing, and a deployed position in which the at least one solar panel is deployed to expose the opening of the housing.

The housing of the vehicle trailer may be divided into multiple compartments that are thermally separated from one another, with the multiple compartments including an upper power inverter compartment within which the at least one power inverter and the at least one cooling unit are disposed, and a lower battery compartment to house multiple rechargeable batteries so as to weigh down the vehicle trailer.

The at least one dedicated cooling unit can include a controller to pre-emptively control the temperature of the at last oner power inverter based on predicted power consumption determined by a machine learning engine.

In another aspect, a method for operating a power system is disclosed that includes converting direct current (DC) provided by at least one battery, using at least one power inverter electrically coupled to the respective at least one battery, into alternating current (AC) supplied to one or more loads, and controlling operation of at least one dedicated cooling unit physically coupled to at least a part of a respective one of the at least one power inverter module to control the temperature of the at least one power inverter.

Embodiments of the above method may include at least some of the features described in the present disclosure, including at least some of the features described above in relation to the system, as well as one or more of the following features.

The at least one power inverter can include a power inversion circuit to produce AC output from DC input supplied by the at least one battery, an inverter housing in which the power inversion circuit is disposed, and a heat draining contact disposed on the inverter housing and being in thermal communication with the power inversion circuit so as to receive thermal energy produced by the power inversion circuit during operation. The at least one cooling unit can be attached to the heat draining contact to thermally control temperature of the at least one power inverter.

The at least one cooling unit may include a solid-state heat pump with a contact element physically attached to a heated portion of the at least one power inverter. Controlling operation of at least one dedicated cooling unit may include controllably transferring heat, based on the temperature of the at least one power inverter, from the contact element to another portion of the solid-state heat pump located remotely from the heated portion of the at least one power inverter.

The solid state heat pump can include a proximal substrate attached to the heated portion of the at least one power inverter, a distal substrate opposite the proximal substrate, and one or more thermoelectric coolers (TEC) disposed between the proximal substrate and the distal substrate. Controllably transferring heat may include increasing current flowing through the one or more TEC, in response to an increase of the measured temperature of the at least one inverter, to cause the distal substrate to cool down so as to draw heat from the proximal substrate.

The method may further include capturing solar energy using at least one solar panel coupled to the power system, and converting the solar energy to electrical energy stored in the at least one battery.

Controlling operation of the at least one dedicated cooling unit may include pre-emptively controlling the temperature of the at last oner power inverter based on predicted power consumption determined by a machine learning engine.

Other features and advantages of the invention are apparent from the following description, and from the claims.

### BRIEF DESCRIPTION OF THE DRAWINGS

These and other aspects will now be described in detail with reference to the following drawings.

FIG. 1 is a front perspective diagram of a power system with DC-battery-carrying portable trailer that includes temperature-controlled inverters.

FIG. 2 is a perspective diagram of the power system housed within a power cabinet of the power system of claim 1.

FIG. 3 is a side-view diagram of an example cooling unit used together with an inverter.

FIG. 4 is a flowchart of an example procedure for operating a battery-based power system.

Like reference symbols in the various drawings indicate like elements.

### DETAILED DESCRIPTION

Disclosed herein is a proposed framework for a large-scale clean power storage and delivery system (which optionally may be portable), equipped with improved dedicated temperature control devices to achieve efficient power delivery to connected loads. In various embodiments, the proposed framework includes a power system with dedicated cooling-mechanisms for the one or more inverters to convert DC power into AC power (e.g., for loads/applications that require AC power instead of DC power, for example, to charge electrical vehicles, operate emergency lights, etc.). As will be discussed in greater detail below, the inverter-dedicated cooling units are used to reduce the temperature and increase the efficiency of inverters that output electricity to AC base electrical devices plugged into a battery management system. In some embodiments, the large-scale power system is equipped with solar panels (e.g., for use in conjunction with a portable trailer-based platform) that can be selectively deployed and used to charge one or more of batteries (even as others of the framework's batteries are delivering power).

DC to AC power systems are coupled to one or more inverter circuits configured to convert DC current to AC current (e.g., through switch-controlled conversion circuit configurations). Because the integrated inverter(s) of the proposed framework are very sensitive to temperature changes (e.g., their efficiencies can drop by as a much as 50% even for modest changes in temperature), controlling the operating temperature of the one or more inverters is one of the keys for improving the efficiency of the system. Accordingly, the proposed framework uses individual dedicated cooling (air conditioning) units that can control the temperature for individual units, and are configured (in some embodiments) to operate using DC power (and can therefore draw power directly from the batteries of the framework without needing to undertake electrical conversion procedures to implement temperature control for the inverters). Examples of short-range, DC-operated cooling (air conditioning) units that can be combined with the power system described herein include a solid-state heat pumps to remove heat generated by operation of the at least one power inverter, a heat-exchange DC-operated air conditioning unit, etc.

Thus, embodiments of the proposed framework described herein include a power storage and supply system including at least one battery to supply direct current power, at least one power inverter electrically coupled to a respective one of the at least one battery, with the at least one power inverter module configured to convert direct current (DC) outputted by the at least one battery into alternating current (AC) supplied to one or more loads, and at least one dedicated cooling unit physically coupled to at least a part of a respective one of the at least one power inverter module to control the temperature of the at least one power inverter. In some example embodiments, the system may be a portable system with its own energy capture/replenishment modules. For example, the system may include at least one solar panel to capture solar energy, and convert the solar energy to electrical energy stored in the at least one battery. In other examples, the power system can use wind turbine, or other mechanisms to harvest clean energy. The power system may also implement a battery management system to control the distribution of power to connected loads based on present power needs of the loads or future (anticipated) needs. As part of controlling load distribution to various connected loads, such a battery management system may also be configured to electrically connect the batteries and the inverter according to different configurations. For example, when needed, multiple batteries may be connected in series in order to provide sufficient power to a load with a large power requirement. The battery management system (also referred to as BMS) may also configure the inverters to operate in parallel (thus feeding several different loads), or to be wired to operate as a cascade of inverters (an inverter daisy chain). The battery management system is also configured to set the proper electrical connections to direct power from the solar panel(s) to the load or to the batteries (for recharging).

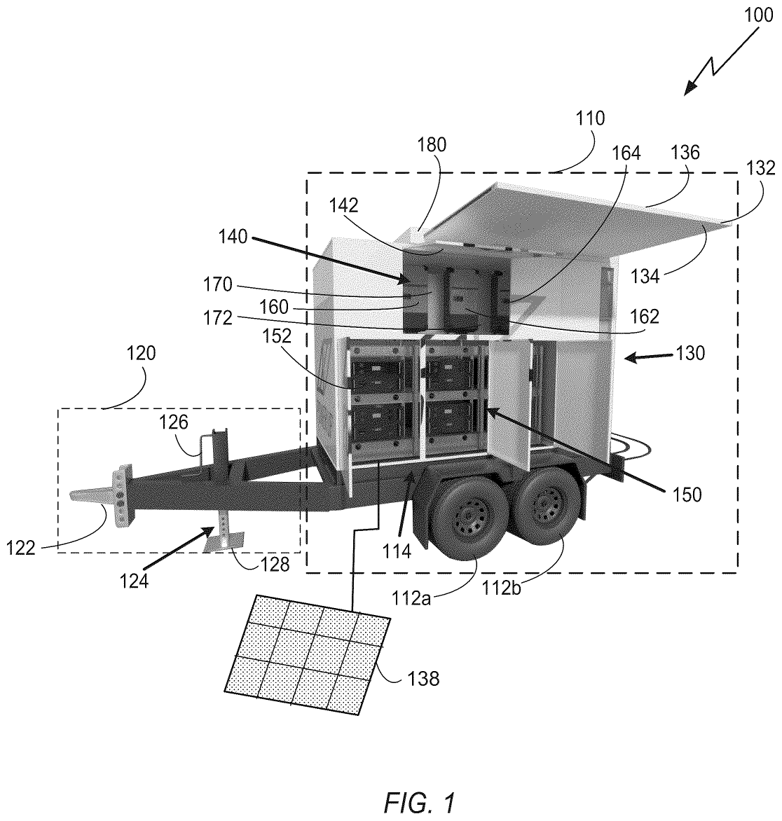

Before discussing in greater detail the heat/temperature management implementation for inverter circuitries used with large-scale DC-to-AC power conversion system, an example embodiment of one such large-scale DC-to-AC power conversion system will be discussed. FIG. 1 is a front perspective view of an assembly of a portable power system 100 that can be transported to remote locations where regular power delivery arrangements are missing or insufficient. As can be seen, the assembly 100 includes a trailer frame with a rear section 110, that includes a power cabinet 130 comprising power components/modules (through which power is delivered to loads at the site to which the trailer assembly was transported). The rear section 110 is supported by four wheels, of which two wheels, 112a and 112b are visible. A front section 120 of the assembly includes a hitching assembly, implemented with a hitching tapered engaging piece 122 that is fitted into a receiving piece (not shown) mounted on a vehicle (also not shown) that transports the trailer assembly 100 to its destination. The front section 120 of the assembly 100 typically also includes an adjustable stand (jack) 124, whose height can be adjusted through a threading mechanism, and a crank 126. When the stand 124 is deployed (after the assembly 100 has reached its destination), a base 128 of the stand 124 allows the otherwise portable trailer assembly 100 to achieve stability (inhibiting movement of the trailer assembly 124). By adjusting the height of the stand 124, the rear section 110 of the trailer assembly can be leveled relative to the surface on which the trailer assembly 100 is resting.

As further depicted in FIG. 1, the rear section 110 includes a rack (support frame) 114 that is fixedly secured to the trailer's frame 110, e.g., through welding and/or through other fastening mechanisms suitable for attaching/fastening metal parts to each other. Mounted to the support frame (also via welding or through suitable fastening mechanism) is a power cabinet 130 in which the power storage and management components of the proposed implementations are housed. The power cabinet 130 includes outer protective displaceable panels that, when the power system is not in operation (e.g., when the trailer assembly, and power cabinet mounted thereon, are in transit), the displaceable panels enclose the power storage devices (e.g., the rechargeable batteries, such as a battery 152) and the accompanying circuitry (control and power delivery circuitry). When the trailer assembly and power system within the cabinet 130 arrive at their destination, at least some of the cover panels, such as cover panel 132, which is configured to be pivotally displaced from a cover position, in which the panel 132 covers and protects the visible front of the power cabinet visible in FIG. 1, to a deployed position, in which the panel 132 is perpendicular to the front of the cabinet, or is tilted at an upward angle, and extends outwardly. The cabinet 130 is generally symmetric in its structure and configuration, and thus another displaceable panel may be moved to a deployed position (symmetrically opposite the panel 132) to allow access to the power cabinet compartment on the back side of the power cabinet 130. As can further be seen from FIG. 1, in some embodiments, the interior of the cabinet 130 (e.g., the upper compartment 140, and the lower compartment 150 where the batteries are stored) may further be covered by smaller access panels, such as panel 142, providing further protection to the components and circuitry within the power cabinet 130. Accordingly, to access the interior upper compartment 140 of the power cabinet 130, the cover panel 132 would need to be pivotally displaced to its deployed position to expose the panel 142, and the panel 142 would need to be similarly pivotally displaced (through approximately 90°, pivoting along the top horizontal side of the window that was covered by the panel 132) to open and provide access to the interior of the upper compartment 140. Similarly, the lower compartment of the power cabinet can be opened to provide access to the interior of the lower compartment 150 (where the high capacity rechargeable batteries are stored) by pivotally displacing, for example, panel 152 (similar to the pivotal displacement of the panel 132 to its deployed position).

In some embodiments, the panel 132 may be a solar panel in which the hidden surface 136 includes an array of photovoltaic (PV) cells (a bottom surface 134 of the panel 132 may act as a further protective cover of the cabinet 130 when the panel 132 is pivoted to its deployed position). The PV cells convert light incident on the cells into electrical current that can be used to recharge one or more of the high capacity rechargeable batteries in the power cabinet 130. As noted, a symmetrically opposite panel may be extending outwardly from the back of the power cabinet 130. It is noted that in embodiments in which the panel 132 is a solar panel, while in transit the solar panel surface may be covered by a protective surface (not shown) to guard the solar panel(s) from damage it might suffer en route. The trailer assembly 100 of FIG. 1 may include additional solar panels (e.g., in addition to the panel 132 and its symmetrical opposite) that can be mounted, for example, on the power cabinet 130 (e.g., on the roof of the power cabinet), or placed in the vicinity of the trailer assembly, such as the modular solar panel 138. In embodiments in which the assembly 100 includes solar panels, electric energy generated through such solar panels may be used to charge one or more of the batteries (such as the battery 152) during periods in which the power cabinet is idle (not delivering electric power to connected loads), deliver power to one or more of the batteries while some of the other batteries are being used to power the connected loads, or directly delivering power to the loads via inverters, such as the inverters 160, 162, and 164 (configured to convert DC power to AC power) disposed in the power cabinet 130 (FIG. 1 shows the front surfaces of the housings of the inverters 160, 162, 164).

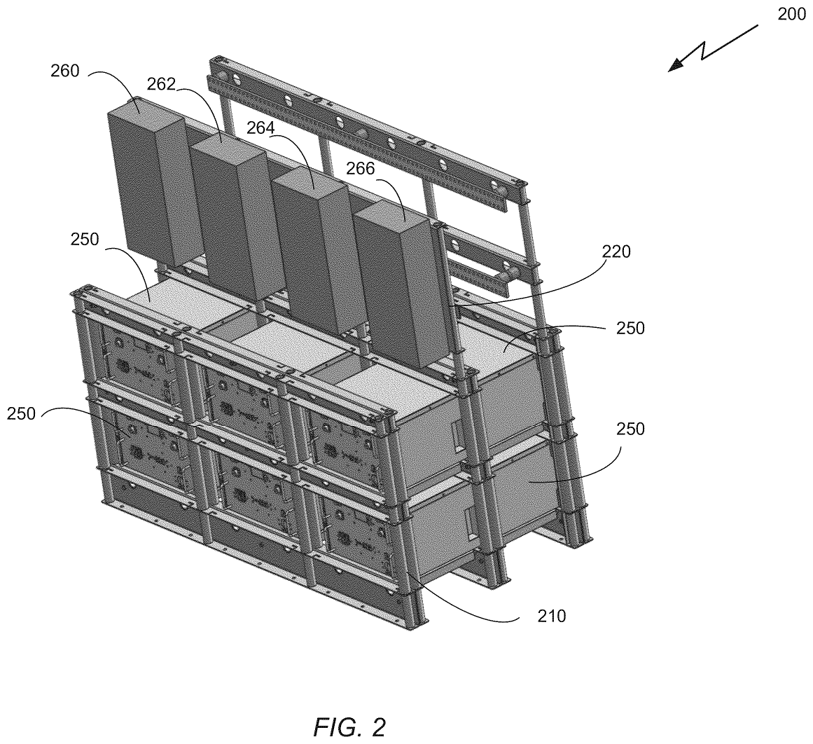

With reference next to FIG. 2, a perspective diagram of the power system 200 housed within the power cabinet 130 of FIG. 1 is shown. The power system 200 includes multiple high capacity rechargeable batteries 250, such as Lithium ion rechargeable batteries, which are arranged in a rack 210. As depicted in FIG. 2, the batteries 250 are arranged in a symmetrical array configuration in which the rack is divided into a front portion and a symmetrical rear portion. Each of the rack's portions is divided into an array of drawers. For example, the front portion of the rack 210 of FIG. 2 includes two rows of drawers with each having three drawer spaces into which high capacity batteries are fitted. The rear portion of the battery rack 210 includes a similar arrangement of an array of drawer spaces. However, the rear portion and the front portion of the battery rack 210 do not need to symmetrical, and in fact the rack may include only a single portion of drawer spaces, arranged in any arbitrary configuration, to accommodate the batteries 250. In some situations, the batteries may be arranged in the rack in a way that increases the stability of the portable assembly (using the weights of the batteries for stability).

As can further be seen in FIG. 2, in some embodiments, each of the batteries 250 has a rectangular box-shaped housing with a front face that includes control knobs and buttons that are used to control the behavior of the batteries. The batteries 250 also each includes handles to pull of push the batteries 250 into their designated drawer spaces. The housings of the batteries 250 may each include slides fastened at various locations on the surfaces of the batteries' housings, with those slides interacting with rails/tracks that are arranged at complementary locations on the rack 210 (e.g., secured to the frame structure that defines the drawer spaces of the rack 210) to allow the batteries to be easily pulled or pushed into their respective drawer spaces for battery maintenance or replacement purposes.

As noted, in various embodiments, each battery of the power system 200 (FIG. 2 illustrates a total of twelve batteries, with six batteries fitted into the front portion of the rack 210 and six batteries fitted into the rear portion of the rack 210) may be a high capacity rechargeable battery. An example of a battery such as the ones used in conjunction with the power system 200 is a lithium and lead acid battery with a nominal voltage of 48V, a maximum charging/discharging current of between 120 A to 210 A, and a voltage range of 40-60V. Other types of high power rechargeable batterie, such as sodium ion batteries, may be used in addition to or instead of the lithium ion batteries.

To supply AC power from the DC batteries 250 of the power system 200, inverters, such as inverters 260, 262, 264, and 266, are mounted on a mounting wall 220 extending from an upper beam of the rack 210 on which the battery drawers are assembled. By having the batteries housed in a rack below where the inverters are mounted, the stability of the trailer assembly 100 (in which the power system 200 is housed) is improved since the heavy batteries help weigh down the trailer assembly (the inverters weigh much less than the batteries). In some embodiments, the rack on which the batteries are housed can be configured to allow some shifting of the relative positioning of the batteries within the rack (e.g., individual drawers housing respective batteries may be allowed to slightly shift or slide) in response to motion of the trailer assembly to help physically place the heavy batteries in more optimal positioning that helps the trailer maintain better balance. In some embodiments, the heights and widths of shelves/drawers built in the trailer assembly 100 to house the batteries can be adjusted to improve the overall weight distribution, and thus improve the balance of the trailer assembly. Furthermore, some example embodiments may include compartments to hold counterbalance weights (e.g., heavy objects having no other utility) that help balance the trailer assembly.

As can be seen from FIG. 2, in some embodiments, the inverters 260, 262, 264, and 266 are mounted in a way that they are mechanically separated from each other and from the batteries 250 (indeed, the inverters and batteries may each be housed in physical compartments that are physically isolated from each other as shown in FIG. 1) such that the inverters do not come in physical contact with any of the other inverters or with the batteries. While this configuration requires slightly larger space/volume to arrange the inverters units, batteries, and structures on which the electrical units are mounted (e.g., the rack 210 and the mounting wall 220) into the assembly that is the power system 200, physically separating the inverters 260-266 from each other and the batteries facilitates temperature control of the inverters and mitigates some of the temperature-related issues that affect the operation and efficiency of the inverters in that it allows dedicated (individual) temperature control approaches for each of the inverters to handle heat generated by the inverter themselves, as well as heat generated by the components of the power system 200.

The inverters 260-266 (the internal circuitry is not shown; rather, the inverters' housings depicted in FIG. 2 represent the inverters' implementations) are high power inverters that are electrically coupled to the DC batteries, e.g., via electrical cables that pass through suitable tubing, through hollow parts of the rack 210 or the mounting wall 220, or that may be tied to parts of the rack 210 and/or mounting wall 220, and are connected to output terminals of the DC batteries 250. As noted, the inverters of the power system 200 may directly convert DC voltage produced by PV cells of solar panels that are deployed from stow-away positions within in an assembly, or which may be standalone modular panels (such as panel 138 depicted in FIG. 1) that may be placed in the vicinity of the trailer assembly and electrically coupled to the inverters 260-266 or to one or more of the batteries 250. Solar panels, whether they are built-in panels, such as the panel 132 of FIG. 1, or supplemental modular panels (such as the panel 138), can be connected to the inverters 260-266 or to the batteries of the power system via one or more electrical switches that can be actuated (for selection of the appropriate electrical path) manually or automatically (using an electromechanical actuation mechanisms).

The inverters 260-266 may be power inverters configured to convert DC voltage input into an AC voltage output using a combination of controllable switching devices (e.g., active switches such as transistors), transformers, and energy storage devices (capacitors or inductors). One or more controllers (individually for each inverter, and/or a global one to control multiple inverters to operate in unison) are used for dynamically switching the DC current flow on and off in a manner that results in the generation of an AC current approximation at the output of the inverters (with electrical characteristics, such as voltage, frequency and phase, that are set according to the desired output application requirements). The multiple inverters of the power system 200 (which may include fewer or more than the four inverters depicted in FIG. 2) can be electrically configured to operate in parallel (with each inverter connected to one or more of the batteries 250 shown in FIG. 2), or as a cascade of one or more inverters such that the output of one inverter is provided as input to the downstream inverter). The configuration of the inverter (e.g., to operate in parallel, or as a cascade of inverters) can be controlled by a controller (e.g., processor-based; not shown in the figures) of the battery management system implemented as part of the power system 200.

The multiple inverters 260-266 of FIG. 2 may each be an Amensolar® N3H-X Series Hybrid inverter. For example, when an N3H-X10-US inverter is used, the nominal output power Output to Grid is 10 KVA, the maximum apparent power Output to Grid is 11 KVA, the output voltage range is 110-120/220-240V (split-phase), 208V (⅔ phase), 230V (1 phase), the output frequency is 50/60 Hz (45 to 54.9 Hz/55 to 65 Hz), the nominal AC current output to grid is 41.7 A, the maximum AC current output to grid is 45.8 A, the output power factor is 0.8 leading . . . 0.8 lagging, and the output total harmonic distortion ratio (THDU) is less than 2%. Other types of high power inverters may be used instead of, or in addition to, the Amensolar® inverters described herein.

As can be seen from FIG. 1 and FIG. 2, the potentially large output power that can be delivered by the power systems (which comprises a large number of batteries housed on the rack 210 of the power system 200) can result in the generation of a lot of heat within the power system. Some of the heat can be removed using an exhaust system that carries heat away from the power system, as well as a global cooling system (such an air conditioning system to cool the power system). However, operation of the inverters is greatly impacted by even small changes in the temperature operating conditions of the power system 200. For example, if the temperature of the inverters exceeds some threshold temperature (e.g., 120° F.), the efficiency of the inverters can go down by 25-50%. It is therefore important, to achieve satisfactory operation of the power system 200, to carefully control the temperature of the inverters. The approaches described herein implement efficient, individualized temperature control that can be separately applied to each of the inverters to maintain their temperature at a desired temperature level or range.

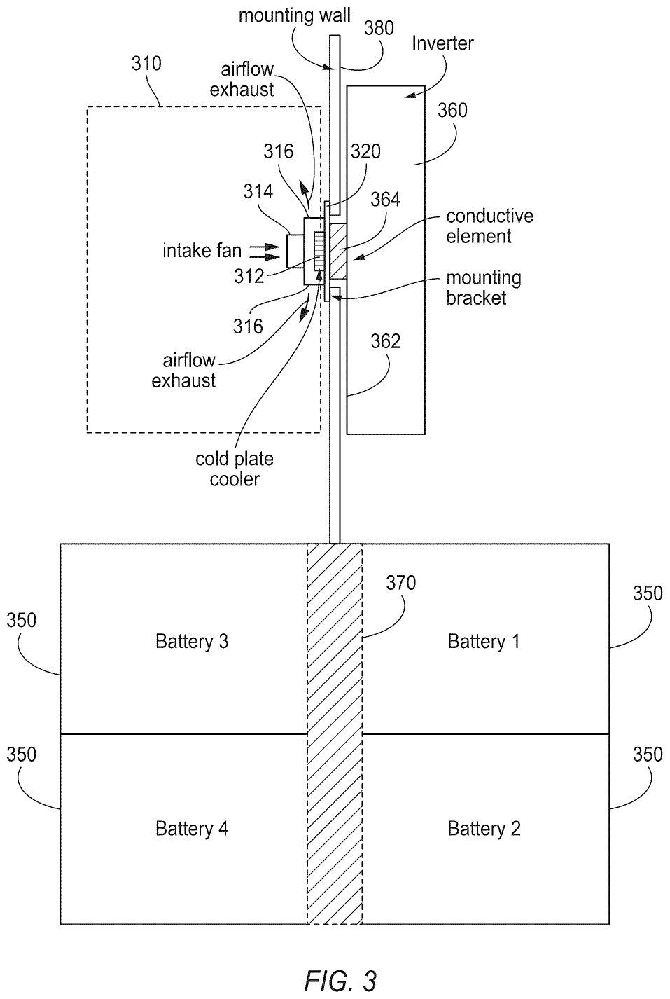

More particularly, with reference to FIG. 3, a side-view diagram 300 of an example inverter cooling unit 310 used together with an inverter 360 (which may be similar in its configuration and implementation to any of the inverters 260-266 depicted in FIG. 2) is provided. Similar to the inverters in FIG. 2, the inverter 360 is mounted on a mounting 380 wall extending upwards from a rack 370 (for simplicity, only a central frame of the rack is illustrated) in which the batteries 350 (which may be similar to the batteries 250 of FIG. 2) are housed. The inverter 360 may be mounted to the mounting wall using a mounting bracket 320. The bracket 320 may include holes or bores into which fasteners (e.g., bolts or screws) are fitted and received within complementary holes or bores (not shown) defined on a back surface 362 of the inverter 360 and/or within the mounting wall 380. The inverter 360 may be mounted onto the mounting wall in other ways, using other fastening mechanisms, e.g., by welding the inverter to the mounting bracket and/or the mounting wall, by using magnets, cables, anchors, and other conventional fastening implements and techniques.

As further shown in FIG. 3, the inverter 360 includes a heat conductive element 364 that is fitted into an opening defined on the back surface 362 of the inverter 360. The heat conductive element is fabricated from good heat conductive materials such as copper or silver. The heat conductive element may, in some embodiments, have a thickness (depth) that causes it to protrude from the back surface 362 of the inverter 360 and to fit, at least partially, through the space defined by the mounting bracket, and to come in physical contact with a cold exterior plate 312 of the inverter cooling unit 310. The protruding heat conductive element 364 may be attached to cooling unit 310 through various fastening/coupling mechanisms (e.g., by snugly fitting the conductive elements into a similarly shaped and dimensioned groove/depression defined on the cold exterior plate 312, by using screws and screw holes to attach the two pieces, by using magnets, adhesives, etc. Alternatively, in some embodiments, the heat conductive element may be secured to the frame of the mounting bracket 320 at the side of the frame facing the conductive element. In such embodiments, the cold exterior plate 312 may be placed through the opening defined by the mounting bracket to come in direct contact with the heat element 364, whereupon the two pieces are secured to each other. For example, the surface of the cold plate that contacts the heat conducting element may snugly be fitted into a depression defined in the heat conductive element, or the cold plate and the heat conductive element may be fastened to each other via screws (or other type of fastening means), etc. Preferably, the inverter 360, as well as any other inverter that may be used in the power system (e.g., in the illustrated example of FIG. 2, four (4) inverters are used) should be insulated from the inverter mounting wall and be attached directly to a respective solid state heat pump (which is mounted on the back side of the mounting wall), thus allowing to isolate just the inverters for thermal management using the dedicated cooling unit. In some examples, a single cooling unit (such as the unit 310) may be attached to the conductive heat plates of multiple (and in some cases, all) inverters such as the inverter 360.

It is to be noted that while FIG. 3 illustrates only one conductive element for coupling with a cold plate, the inverter 360 may include additional conductive elements (which may be distributed on multiple surfaces of the inverter's housing). Furthermore, the heat conductive element 364 may be dimensioned and shaped so that it extends over a large portion of the back surface 362 (and/or additional inverter housing surfaces). For example, the heat conductive element may extend over greater than 50% of the surface area of the back surface 362 of the inverter 360.

As illustrated in FIG. 3, the cooling unit includes the cold exterior plate 312, which implements a miniature, air-conditioning unit that can be powered by DC current (from the batteries 350, or from DC current generated via solar panels, such as the solar panel 138 depicted in FIG. 1) used with the power system 200. An example of a miniaturized cooling unit that can be combined with temperature sensitive components, such as the inverter 360 of FIG. 3 is a solid state air condition unit such as the air conditioning units manufactured by Phononic Devices, Inc. The use of a DC-power cooling unit(s) helps streamline the overall power efficiencies of the power system in that not only are the power requirements for running the cooling unit(s) relatively low (partly because solid-state heat exchangers require relatively less power (compared to conventional air conditioning units), and partly because of the ability to quickly modulate the cooling operation of the cooling unit based on the temperature of the inverter in a way that helps maintain the operation of the inverters as efficient as possible).

Briefly, an example air conditioning unit implementing a heat exchange mechanism in which heat is removed from a hot interior of the inverter's housing and is ejected to the outside area is the heat exchange mechanism implemented using semiconducting plates (referred to as thermoelectric coolers, or TEC) that are controlled by a controller (e.g., processor-based device, or a simpler control mechanism to actuate on and off the flow of current). The TEC plates are placed between thermally conductive substrates. When the TEC solid state plates are activated, current flows in the TEC plates outwardly (away from the chamber), thus creating a hot side heat sink (the outward distal substrate) and a cold side heat sink, which is the substrate (proximal substrate) that is in physical contact with the hot chamber (e.g., inverter housing) that is to be cooled. As a result, the proximal substrate (transferring its heat to the distal substrate) acts a condenser, while the distal substrate acts as an evaporator. Further details regarding the solid-state implementation for thermal control are provided, for example, at US 2013/0291555, entitled “[t]hermoelectric refrigeration system control scheme for high efficiency performance,” the content of which is hereby incorporated by reference in its entirety. An example a thermoelectric cooler that may be used in conjunction with the inverters described herein is the CP-200HT thermoelectric coolant module, sold by TE Technology, Inc.®

To facilitate the heat removal from the housing of the inverter 360, tubing (plumbing) to circulate two-phase coolant fluid through interior area of the inverter's housing can be installed within the inverter, with the tubing routed to the cold plate interface. Such tubing can be aligned along the interior walls of the housing of the inverter 360 to form one or more heat exchange loop originating and ending at heat conductive element 364 connected to the back surface 362 of the inverter 360 (as noted, the heat conductive element is physically attached to the cold exterior plate, or more particularly to the proximal substrate in embodiments based on the TEC heat exchange implementation). Alternatively and/or additionally, in some embodiments, the interior space of the inverter 360 (i.e., within the housing of the inverter 360) may be fitted with a network of heat conducting wirings or strips that are attached to the heat conductive element 364. In such embodiments, when the TEC plates become active (creating a hot distal substrate, and a chilled/cold proximal substrate that is in physical, and thus thermal contact with the heat conductive element 364), heat within the inverter 360 will be conducted along the heat conducting wiring and strips to the relatively cold heat conductive element 364. From there, the heat moves, via the cold proximal substrate, and through the activated TEC elements, to the distal substrate of the cold exterior plate 312. Additionally, in various embodiments, the interior space of the inverter 360 can also be fitted with fans to blow out hot air, created inside the inverters, in the direction of the heat conductive element 364. It is to be noted that the controller (not specifically shown) controlling the operation of the cooling unit 310 may be configured to dynamically regulate the activity of the TEC plates so as to increase or decrease the current flowing through individual TEC plates, thereby controlling (regulating/modulating) the rate of heat transfer from the interior of the inverter to the cooling unit. For example, by increasing the current flow in the TEC plates, the controller can cause the distal substrate to become hotter, thus lowering the temperature at the proximal plate and the conductive heat element attached thereto. The controller can select specific TEC plates to activate, and also control characteristics of the currents flowing through the selected TEC plates (e.g., amplitude, duty cycle, waveform, etc.) The control procedure allows for careful adjustments of the heat removal operations applied to the inverter 360, and optionally to the other inverters arranged in the trailer assembly, to control the inverters' temperature.

The control operation can be performed dynamically, e.g., based on sensor measurements (and/or based on other data sources) indicative of temperature conditions within the inverter. For example, the inverter 360 can be equipped with one or more thermometers (e.g., one or more thermistors). Measurement indicating a temperature increase within the inverter may cause the controller to cause a higher current to flow through the TEC plates to distal substrate, which in turn will cause the temperature at the proximal substrate and at the cold exterior plate to decrease (increase in the current flow through the TEC plates increases the cooling capacity of the cooling unit 310).

In some embodiments, the cooling unit may be implemented using other types of cooling systems. As another example, the cooling unit 310 may include a DC operated air-conditioner unit, such as the Kingfisher MA37X12B Marine Air Conditioner manufactured by Archer Power Solutions. A further example of a cooling system that may be incorporated into the power storage and delivery framework described herein is a magnetic cooling/refrigeration-based system (operating based on the magnetocaloric effect). Under this refrigeration approach, a suitable magnetocaloric material (e.g., a Gadolinium alloy) is exposed to a magnetic field, causing the material to heat up. The material is configured to dispose of some of the heat (e.g., by radiating or transferring heat through a coolant medium) generated as a result of the application of the magnetic field, and upon removal of the magnetic field, the magnetocaloric material re-absorbs the remaining heat, causing the materials to cool down to a temperature lower than its starting temperature. Yet another example of a cooling mechanism that may form the basis for a temperature control system for the DC power storage and delivery systems' described herein is an electrocaloric cooling mechanism. Similar to the magnetocaloric effect, the electrocaloric effect causes a suitable material to heat up when an electric filed is applied to the material. Removal of the heat (by radiation or by using a coolant), and termination of the electric field will cause the electrocaloric material to cool down, preferably to a temperature below its starting temperature (due to removal of the heat from the material). Other types of cooling mechanisms may also be used to cool the power storage and delivery embodiments described herein.

In some embodiments, the controller may be configured to pre-emptively regulate the operation of the cooling unit(s) based on anticipated/expected changes to the consumption of power to be delivered from the batteries (via the inverters). For example, the controller (or controllers, if each inverter is controlled by a dedicated controller) may be coupled to a machine learning engine that is used to predict increases and decreases in the power about to be delivered by the batteries of the power system. For instance, if the power system is to be used in a venue where an event is taking place during which there are several periods where there are expected upticks in the usage of the power system (e.g., during intermission periods), the machine learning engine can be trained to generate output that would pre-emptively start operation of the cooling unit(s) used with the inverters in order to pre-emptively start cooling the inverters. In some embodiments, the controller (or controllers) can determine the individual heat removal functionality of each inverter, e.g., to activate or turn off hear removing operations within the various inverters. The determination on how to regulate the hear removal operations (and/or whether to do so pre-emptively) may depend on the age of the various inverters. For example, older inverter may require more aggressive pre-emptive control of the heat removal functionality in order to avoid malfunctioning of those inverters. Thus, in situations in which the inverters' temperatures are increasing (or are expected to increase), the controller(s) may initiate heat removal operations at the older inverters that have a higher likelihood to fail. In some further examples, the efficacy of heat removal of each individual inverter may be continually observed, and used to adjust the control functionality of the individual inverters. For instance, inverters that are observed to be more responsive to heat removal operation may be given preference when seeking to control the overall performance of the inverters (and/or the inverters' heat removal behavior). In another example, inverters that are observed to spend more energy to control cooling operations (e.g., due to inefficiencies of those inverters) may require pre-emptive triggering of the respective cooling systems for those inverters to present a more favorable operating environments for those less efficient inverters.

In another example, the machine learning engine may receive as input signals from motion sensors that would indicate whether the trailer is in motion and/or covering panel protecting the power systems are closed. Thus, even if the temperature measured by one or more thermometers deployed within the power system indicate high temperature (e.g., because it is a hot day), the cooling units do not have to be turned on if the motion sensors indicate the power system (or more particularly, the trailer assembly) is in motion. The machine learning engine may be trained using training data defining the ground truth (e.g., determining what the outputs of the machine learning engine should be for the particular input information being fed to the input stage of the machine learning engine).

As further illustrated in FIG. 3, the cooling unit 310 also includes an intake fan 314, and two airflow exhausts 316 (oriented in a parallel direction to the plane defined by the mounting wall 380 or the plane define by the back surface 362 of the inverter 360). Heat transferred from the inverter 360, via the heat conductive element 364, the proximal substrate of the cold exterior plate 312, the TEC plates, and the distal substrate of the cold exterior plate is ejected through the airflow exhausts 316 (the ejected heat may subsequently be ejected power system 200 through a separate thermal control system, that may also include fans to remove heated air from within the interior of the power system). In some embodiments, the exhaust system used for the inverters (e.g., the intake fan 314 and the airflow exhausts 316 used for the inverter 360) may be turned on only after the temperature of the inverters (as determined by one or more thermometers coupled to the inverters of the power system described herein) has increased. Operation of the exhaust system may be independent of the operation of the cold exterior plate (i.e., the heat exchange). It is noted that the decisions on how to regulate the temperature of the inverter(s) may also be based on the type of batteries that are being used (e.g., different type of batteries discharge at different rates, thus impacting the overall generation of heat by the batteries). It will further be noted that the controller may control additional modules and devices of the power system to regular their operation. For instance, efficiencies of batteries can decrease at low temperature. Therefore, the controller may be configured to generate heat by turning the exhaust fans on, by causing heating elements in the vicinity of the batteries to be turned on, etc.

In addition to the cooling implementations used to control the temperature of the inverters, the power systems described herein may include additional mechanisms to maintain efficient (optimal or near optimal) operating conditions of the power systems described herein. For example, the power systems (such as the power system 200 shown in FIG. 2) may be equipped with heat removal systems that include fans and dedicated structures through which heat generated during operation of the power systems can be removed. For instance, FIG. 1 shows two heat removal ducts (exhausts) 170 and 172, disposed within the upper compartment 140, that provide a path for heated air produced during operation of the batteries (when delivering power, via the inverters, to various loads) to escape from the lower compartments 150 to outside the assembly comprising the power system. In FIG. 1, the ducts 170 and 172 are connected to a roof top 180, which may include vents through which the heated air is ejected. While not specifically shown, air traveling via the ducts 170 and 172 may be pushed out by fans disposed within the assemblies shown in FIGS. 1 and 2. In some embodiments, the compartment housing for the batteries may be equipped with exhaust fan system that push heated air to side vents located on side surfaces of the lower compartment (thus avoiding blowing heated air to the upper compartment housing the inverters). Other heat removal structures (ducts, heat sinks, vents, air cooling units) may also be included to control the temperature (and thus the overall operation) of the power systems described herein.

As noted, implementing the proposed framework and performing the various techniques and operations described herein may be facilitated by a controller device(s) (e.g., a processor-based computing device). Such a controller device may include a processor-based device such as a computing device, and so forth, that typically includes a central processor unit or a processing core. The device may also include one or more dedicated learning machines (e.g., neural networks) that may be part of the CPU or processing core. In addition to the CPU, the system includes main memory, cache memory and bus interface circuits. The controller device may include a mass storage element, such as a hard drive (solid state hard drive, or other types of hard drive), or flash drive associated with the computer system. The controller device may further include a keyboard, or keypad, or some other user input interface, and a monitor, e.g., an LCD (liquid crystal display) monitor, that may be placed where a user can access them.

The controller device is configured to facilitate, for example, monitoring environmental characteristics (e.g., temperatures) and various other operating conditions, to, for example, regulate the operation of cooling units (such as those attached to inverters of a power system). The storage device may thus include a computer program product that when executed on the controller device (which, as noted, may be a processor-based device) causes the processor-based device to perform operations to facilitate the implementation of procedures and operations described herein. The controller device may further include peripheral devices to enable input/output functionality. Such peripheral devices may include, for example, flash drive (e.g., a removable flash drive), or a network connection (e.g., implemented using a USB port and/or a wireless transceiver), for downloading related content to the connected system. Such peripheral devices may also be used for downloading software containing computer instructions to enable general operation of the respective system/device. Alternatively and/or additionally, in some embodiments, special purpose logic circuitry, e.g., an FPGA (field programmable gate array), an ASIC (application-specific integrated circuit), a DSP processor, a graphics processing unit (GPU), application processing unit (APU), etc., may be used in the implementations of the controller device. Other modules that may be included with the controller device may include a user interface to provide or receive input and output data. The controller device may include an operating system.

Computer programs (also known as programs, software, software applications or code) include machine instructions for a programmable processor, and may be implemented in a high-level procedural and/or object-oriented programming language, and/or in assembly/machine language. As used herein, the term “machine-readable medium” refers to any non-transitory computer program product, apparatus and/or device (e.g., magnetic discs, optical disks, memory, Programmable Logic Devices (PLDs)) used to provide machine instructions and/or data to a programmable processor, including a non-transitory machine-readable medium that receives machine instructions as a machine-readable signal.

In some embodiments, any suitable computer readable media can be used for storing instructions for performing the processes/operations/procedures described herein. For example, in some embodiments computer readable media can be transitory or non-transitory. For example, non-transitory computer readable media can include media such as magnetic media (such as hard disks, floppy disks, etc.), optical media (such as compact discs, digital video discs, Blu-ray discs, etc.), semiconductor media (such as flash memory, electrically programmable read only memory (EPROM), electrically erasable programmable read only Memory (EEPROM), etc.), any suitable media that is not fleeting or not devoid of any semblance of permanence during transmission, and/or any suitable tangible media. As another example, transitory computer readable media can include signals on networks, in wires, conductors, optical fibers, circuits, any suitable media that is fleeting and devoid of any semblance of permanence during transmission, and/or any suitable intangible media.

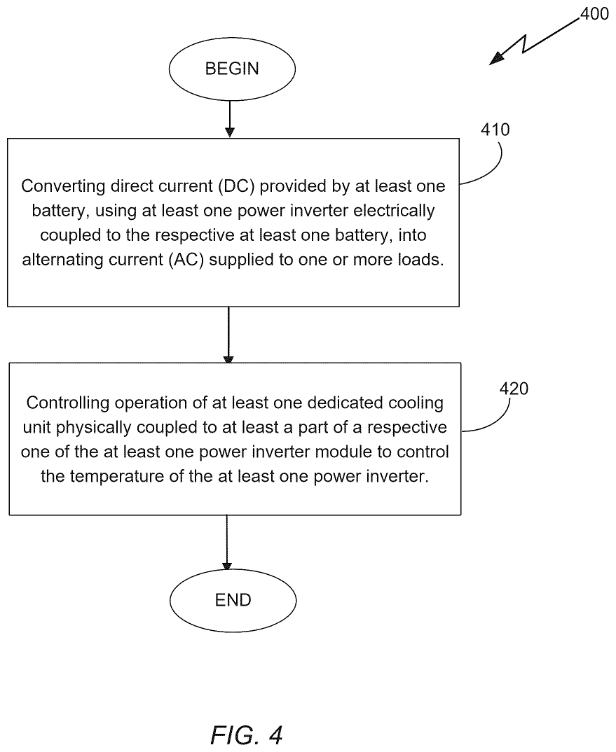

With reference next to FIG. 4, a flowchart of an example procedure 400 for operating a portable power system is shown. The procedure 400 includes converting 410 direct current (DC) provided by at least one battery, using at least one power inverter electrically coupled to the respective at least one battery, into alternating current (AC) supplied to one or more loads, and controlling 420 operation of at least one dedicated cooling unit physically coupled to at least a part of a respective one of the at least one power inverter module to control the temperature of the at least one power inverter.

In some examples, the at least one power inverter may include a power inversion circuit to produce AC output from DC input supplied by the at least one battery, an inverter housing in which the power inversion circuit is disposed; and a heat draining contact disposed on the inverter housing and being in thermal communication with the power inversion circuit so as to receive thermal energy produced by the power inversion circuit during operation. In such examples, the at least one cooling unit is attached to the heat draining contact to thermally control temperature of the at least one power inverter.

In some embodiments, the at least one cooling unit can include a solid-state heat pump with a contact element physically attached to a heated portion of the at least one power inverter. In such embodiments, controlling operation of the at least one dedicated cooling unit may include controllably transferring heat, based on the temperature of the at least one power inverter, from the contact element to another portion of the solid-state heat pump located remotely from the heated portion of the at least one power inverter. The solid state heat pump may include a proximal substrate attached to the heated portion of the at least one power inverter, a distal substrate opposite the proximal substrate, and one or more thermoelectric coolers (TEC) disposed between the proximal substrate and the distal substrate. Controllably transferring heat may include increasing current flowing through the one or more TEC, in response to an increase of the measured temperature of the at least one inverter, to cause transfer of heat from the proximal substrate to the distal substrate. In some examples, the at least one cooling unit can be one of, for example, a DC-operated air conditioning unit, a magnetocaloric-based cooling mechanism, and/or a an electrocaloric cooling mechanism.

In various examples, the procedure 400 may further include capturing solar energy using at least one solar panel coupled to the power system, and converting the solar energy to electrical energy stored in the at least one battery. In some embodiments, controlling operation of the at least one dedicated cooling unit may include pre-emptively controlling the temperature of the at last oner power inverter based on predicted power consumption determined by a machine learning engine.

Unless defined otherwise, all technical and scientific terms used herein have the same meaning as commonly or conventionally understood. As used herein, the articles “a” and “an” refer to one or to more than one (i.e., to at least one) of the grammatical object of the article. By way of example, “an element” means one element or more than one element. “About” and/or “approximately” as used herein when referring to a measurable value such as an amount, a temporal duration, and the like, encompasses variations of ±20% or ±10%, ±5%, or ±0.1% from the specified value, as such variations are appropriate in the context of the systems, devices, circuits, methods, and other implementations described herein. “Substantially” as used herein when referring to a measurable value such as an amount, a temporal duration, a physical attribute (such as frequency), and the like, also encompasses variations of ±20% or ±10%, ±5%, or ±0.1% from the specified value, as such variations are appropriate in the context of the systems, devices, circuits, methods, and other implementations described herein.

As used herein, including in the claims, “or” as used in a list of items prefaced by “at least one of” or “one or more of” indicates a disjunctive list such that, for example, a list of “at least one of A, B, or C” means A or B or C or AB or AC or BC or ABC (i.e., A and B and C), or combinations with more than one feature (e.g., AA, AAB, ABBC, etc.). Also, as used herein, unless otherwise stated, a statement that a function or operation is “based on” an item or condition means that the function or operation is based on the stated item or condition and may be based on one or more items and/or conditions in addition to the stated item or condition.

Although particular embodiments have been disclosed herein in detail, this has been done by way of example for purposes of illustration only, and is not intended to be limiting with respect to the scope of the appended claims, which follow. Features of the disclosed embodiments can be combined, rearranged, etc., within the scope of the invention to produce more embodiments. Some other aspects, advantages, and modifications are considered to be within the scope of the claims provided below. The claims presented are representative of at least some of the embodiments and features disclosed herein. Other unclaimed embodiments and features are also contemplated.

What is claimed is:

1. A power system comprising:
at least one battery to supply direct current (DC) power;
at least one power inverter electrically coupled to a respective one of the at least one battery, the at least one power inverter module configured to convert DC outputted by the at least one battery into alternating current (AC) supplied to one or more loads; and
at least one dedicated cooling unit physically coupled to at least a part of the respective one of the at least one power inverter module to control the temperature of the at least one power inverter.

2. The system of claim 1, wherein the at least one power inverter comprises:
a power inversion circuit to produce output AC from input DC supplied by the at least one battery;
an inverter housing in which the power inversion circuit is disposed; and
a heat draining contact disposed on the inverter housing and being in thermal communication with the power inversion circuit so as to receive thermal energy produced by the power inversion circuit during operation;
wherein the at least one cooling unit is attached to the heat draining contact to thermally control temperature of the at least one power inverter.

3. The system of claim 2, wherein the heat draining contact comprises one or more heat conductive elements inserted into complementary depressions in walls defining the inverter housing, the one or more heat conductive elements connected to one or more heat guides delivering heat produced by the power inversion circuitry to the one or more heat conductive elements.

4. The system of claim 3, wherein the one or more heat guides comprise one or more of: heat conductive wiring, or tubing containing two-phase coolants.

5. The system of claim 1, wherein the at least one cooling unit comprises a solid-state heat pump with a contact element physically attached to a heated portion of the at least one power inverter, the solid-state heat pump causing, when in operation, transfer of heat from the contact element to another portion of the solid-state heat pump located remotely from the heated portion of the at least one power inverter.

6. The system of claim 5, wherein the solid state heat pump comprises:
a proximal substrate attached to the heated portion of the at least one power inverter;
a distal substrate opposite the proximal substrate;
one or more thermoelectric coolers (TEC) disposed between the proximal substrate and the distal substrate; and
a controller to control current flowing through the one or TEC based on measured temperature of the at least one power inverter.

7. The system of claim 6, wherein the controller configured to control the current is configured to increase the current flowing through the one or more TEC, in response to an increase of the measured temperature of the at least one power inverter, to transfer heat from the proximal substrate to the distal substrate.

8. The system of claim 5, further comprising:
an exhaust fan module to remove heat captured by the solid-state heat pump.

9. The system of claim 1, wherein the at least one cooling unit comprises one or more of:
a DC-operated air conditioning unit, a magnetocaloric-based cooling mechanism, or a an electrocaloric cooling mechanism.

10. The system of claim 1, further comprising:
at least one solar panel to capture solar energy, and convert the solar energy to electrical energy stored in the at least one battery.

11. The system of claim 10, further comprising:
a vehicle trailer comprising multiple batteries that include the at least one battery, the vehicle trailer including a housing with a roof, wherein the at least one solar panel is mounted proximate the roof of the vehicle trailer.

12. The system of claim 11, wherein the at least one solar panel is pivotally displaceable between a covered position in which the at least one solar panel encloses an opening of the housing, and a deployed position in which the at least one solar panel is deployed to expose the opening of the housing.

13. The system of claim 11, wherein the housing of the vehicle trailer is divided into multiple compartments that are thermally separated from one another, the multiple compartments including:
an upper power inverter compartment within which the at least one power inverter and the at least one cooling unit are disposed; and
a lower battery compartment to house multiple rechargeable batteries so as to weigh down the vehicle trailer.

14. The system of claim 1, wherein the at least one dedicated cooling unit comprises a controller to pre-emptively control the temperature of the at last oner power inverter based on predicted power consumption determined by a machine learning engine.

15. A method for operating a power system comprising:
converting direct current (DC) provided by at least one battery, using at least one power inverter electrically coupled to the respective at least one battery, into alternating current (AC) supplied to one or more loads; and
controlling operation of at least one dedicated cooling unit physically coupled to at least a part of a respective one of the at least one power inverter module to control the temperature of the at least one power inverter.

16. The method of claim 15, wherein the at least one power inverter comprises:
a power inversion circuit to produce AC output from DC input supplied by the at least one battery;
an inverter housing in which the power inversion circuit is disposed; and
a heat draining contact disposed on the inverter housing and being in thermal communication with the power inversion circuit so as to receive thermal energy produced by the power inversion circuit during operation;
wherein the at least one cooling unit is attached to the heat draining contact to thermally control temperature of the at least one power inverter.

17. The method of claim 15, wherein the at least one cooling unit comprises a solid-state heat pump with a contact element physically attached to a heated portion of the at least one power inverter, wherein controlling operation of at least one dedicated cooling unit comprises:
controllably transferring heat, based on the temperature of the at least one power inverter, from the contact element to another portion of the solid-state heat pump located remotely from the heated portion of the at least one power inverter.

18. The method of claim 17, wherein the solid state heat pump comprises a proximal substrate attached to the heated portion of the at least one power inverter, a distal substrate opposite the proximal substrate, and one or more thermoelectric coolers (TEC) disposed between the proximal substrate and the distal substrate;
wherein controllably transferring heat comprises increasing current flowing through the one or more TEC, in response to an increase of the measured temperature of the at least one inverter, to cause the distal substrate to cool down so as to draw heat from the proximal substrate.

19. The method of claim 15, further comprising:
capturing solar energy using at least one solar panel coupled to the power system; and
converting the solar energy to electrical energy stored in the at least one battery.

20. The method of claim 15, wherein controlling operation of the at least one dedicated cooling unit comprises:
pre-emptively controlling the temperature of the at last oner power inverter based on predicted power consumption determined by a machine learning engine.
